(19) United States
(12) Patent Application Publication
(10) Pub. No.: US 2008/0264468 A1
(43) Pub. Date: Oct. 30, 2008

(54) Solar power unit with enclosed outer structure

(75) Inventors: Peter Young, San Francisco, CA (US); Michael Milbourne, El Granada, CA (US)

Correspondence Address: THE MUELLER LAW OFFICE, P.C., 12951 Harwick Lane, San Diego, CA, 92130, US

(73) Assignee: Sol Focus, Inc., Palo Alto, CA (US)

(21) Appl. No.: 11/796,485

(22) Filed: Apr. 27, 2007

(51) Int. Cl. H01L 31/042

(52) U.S. Cl. 136/246

(57) ABSTRACT

The present invention is a solar power unit which uses at least two mirrors to focus light onto a solar receiver assembly. An outer structure for the solar power unit serves as an enclosure for the solar power unit and incorporates integral features for aligning components within. The integral alignment features reduce the need for costly tooling which is typically required to align optical elements in a solar power unit. Solar energy units may be joined together with interlocking features to form a solar energy array.

### RELATED APPLICATION

This application is related to co-pending U.S. Utility patent application Ser. No. ______[TBD] filed on Apr. 27, 2007 entitled “Solar Power Unit with Integrated Primary Structure” which is hereby incorporated by reference as if set forth in full in this application for all purposes.

### BACKGROUND OF THE INVENTION

It is generally appreciated that one of the many known technologies for generating electrical power involves harvesting solar radiation and converting it into direct current (DC) electricity. Solar power generation has already proven to be a very effective and “environmentally friendly” energy option, and further advances related to this technology continue to increase the appeal of such power generation systems. In addition to having a design that is efficient in both performance and size, a key factor to commercial success is the ability to manufacture such systems in a cost-effective manner through improvements in manufacturability and component design.

Traditional solar energy conversion is achieved by flat-plate technology, in which solar radiation directly impinges upon a large array of photovoltaic cells. Because the cost of photovoltaic cells and the demand for semiconductor materials are both high, the cost of the large surface areas required for this approach is a deterrent to widespread use. In contrast, concentrator photovoltaic (CPV) systems are solar energy generators which increase the efficiency of converting solar energy to DC electricity by using mirrors to focus the intensity of sunlight onto a small, and thus much less expensive, solar cell.

Solar concentrators which are known in the art utilize parabolic mirrors and Fresnel lenses for focusing incoming solar energy, as well as heliostats for tracking the sun's movements in order to maximize light exposure. A new type of CPV system, disclosed in U.S. Patent Application Publication No. 2006/0266408 A1, entitled “Concentrator Solar Photovoltaic Array with Compact Tailored Imaging Power Units,” utilizes two curved mirrors which allow for a compact yet structurally robust design. In this design, solar energy enters the assembly through a front panel. The solar rays reflect off a primary mirror onto a secondary mirror, which in turn reflects and focuses solar energy onto a photovoltaic cell. A back panel and housing enclose the assembly to protect it from environmental elements and to provide structural integrity. The surface area of the solar photovoltaic cell in such a system is much smaller than what is required for non-concentrating systems, for example less than 1% of the entry window surface area. Thus, the reduction in the amount of expensive photovoltaic material results in a greatly decreased cost of the overall assembly.

However, although solar concentrators are feasible in principle and have been under development for many years, they have yet to produce energy at prices which are competitive enough to attain widespread commercial success. The ability to produce energy at a cost-efficient rate hinges upon a design which is highly efficient at producing energy, and which minimizes the cost of manufacturing the system. Because the receiving area of the solar cell is so small relative to that of the power unit, the need for the mirrors to be accurately aligned to focus the sun's rays onto the solar cell is important to achieving the desired efficiency of such a solar concentrating system. Accurate placement of the solar cell and primary and secondary mirrors requires skilled assembly and specialized tooling. Such tooling costs and inherent tolerance errors become propagated when constructing an array of many concentrator units. Components which are designed in such a way to simplify the assembly process would greatly improve the chances of a solar energy system to be successful. Additional considerations such as ease of installation, serviceability, and durability against environmental conditions are also important to the commercial success of a design.

One approach to improving manufacturability is to combine separate components into one piece, thereby reducing the number of parts needing to be assembled. In U.S. Pat. No. 4,716,258 entitled “Stamped Concentrators Supporting Photovoltaic Assemblies,” sheet metal stamping is used to produce a one-piece concentrator unit with an array of slatted, louvered reflectors. The outer frame of the concentrator, along with multiple reflector strips, are stamped and formed as a single component. A slot in the frame is provided for inserting the photovoltaic receiver in the proper location for the array.

Patent application publication U.S. 2006/0231133 A1, entitled “Concentrating Solar Collector with Solid Optical Element,” combines two mirrors by depositing or plating reflective films onto the faces of an optical element. The optical element may be molded from optically suitable materials such as glass or clear plastic. Light travels within the solid optical element, reflecting off primary and secondary mirror surfaces to be focused on a photovoltaic cell. The solid element thus combines two mirrors into one component, which are inherently aligned.

Another way to improve manufacturability as well as serviceability is by utilizing modular units. U.S. Pat. No. 3,350,234 entitled “Flexible Solar-Cell Concentrator Array” describes individual modular units which are elongated trough-like reflectors. The units are intercoupled in a side-by-side relationship to form either a rigid panel or a flexible array, such as by incorporating hinged joints. The modular construction enables malfunctioning components to be easily replaced.

While processes such as stamping and molding have been used in solar energy systems to fabricate various parts, there is the long-felt need to further improve the manufacturability of such systems in order to make solar energy more competitive in the energy market. Reducing the number of components, improving repeatable and accurate alignment of parts, and decreasing material costs while preserving or increasing functional performance are all aspects which continue to be sought after in the solar concentrator industry. This is even more of a challenge in consideration of the fact that each new design requires solutions particular to its individual construction. Further improvements which positively impact the ease of installation, serviceability, and durability against environmental conditions are also highly important.

### SUMMARY OF THE INVENTION

The present invention is a solar power unit which uses one or more mirrors to focus light onto a solar receiver assembly. An outer structure for the solar power unit serves as an enclosure for the solar power unit and incorporates integral features for aligning components within. The integral alignment features reduce the need for costly tooling which is typically required to align optical elements in a solar power unit. In one embodiment, the outer structure is a hexagonal shape. Solar energy units may be joined together with interlocking features to form a solar energy array.

### BRIEF DESCRIPTION OF THE DRAWINGS

FIG. 1 is a cross-sectional view of a basic solar concentrator;

FIG. 2 shows a cross-sectional view of the present solar concentrator with improved outer structure;

FIG. 3 illustrates a perspective view of an exemplary outer structure;

FIG. 4 provides a perspective view of an assembled solar concentrator unit;

FIG. 5 shows a perspective view of an outer structure with connecting means;

FIG. 6A depicts an alternative interlocking means for an outer structure;

FIG. 6B is a cross-sectional view of two interlocking units;

FIG. 7 shows a cross-sectional view of another embodiment of connecting units;

FIGS. 8A and 8B illustrate arrangements of interlocking units in an array;

FIG. 9 provides a cross-sectional view of solar concentrator units joined by clips;

FIGS. 10A and 10B are perspective views of alternative mechanisms for connecting solar concentrator units; and

FIG. 11 is a simplified flowchart for assembling a solar concentrator unit.

### DETAILED DESCRIPTION OF THE EMBODIMENTS

Reference now will be made in detail to embodiments of the disclosed invention, one or more examples of which are illustrated in the accompanying drawings. Each example is provided by way of explanation of the present technology, not limitation of the present technology. In fact, it will be apparent to those skilled in the art that modifications and variations can be made in the present technology without departing from the spirit and scope thereof. For instance, features illustrated or described as part of one embodiment may be used on another embodiment to yield a still further embodiment. Thus, it is intended that the present subject matter covers such modifications and variations as come within the scope of the appended claims and their equivalents.

The assembly and alignment means described in this disclosure may be used with a solar power unit design incorporating optically aligned primary and secondary mirrors. The solar power unit design is described in detail in related, co-pending patent applications as follows: (1) “Concentrator Solar Photovoltaic Array with Compact Tailored Imaging Power Units;” U.S. Patent Application Publication No. 2006/0266408 A1; filed May 26, 2005; and (2) “Optical System Using Tailored Imaging Designs;” U.S. Patent Application Publication No. 2006/0274439 A1; filed Feb. 9, 2006, which claims priority from U.S. provisional patent application No. 60/651,856 filed Feb. 10, 2005; all of which are hereby incorporated by reference as set forth in full in this application for all purposes. Note that variations on the design described in the co-pending applications may be achieved by modifying specific steps and/or items described herein while still remaining within the scope of the invention as claimed.

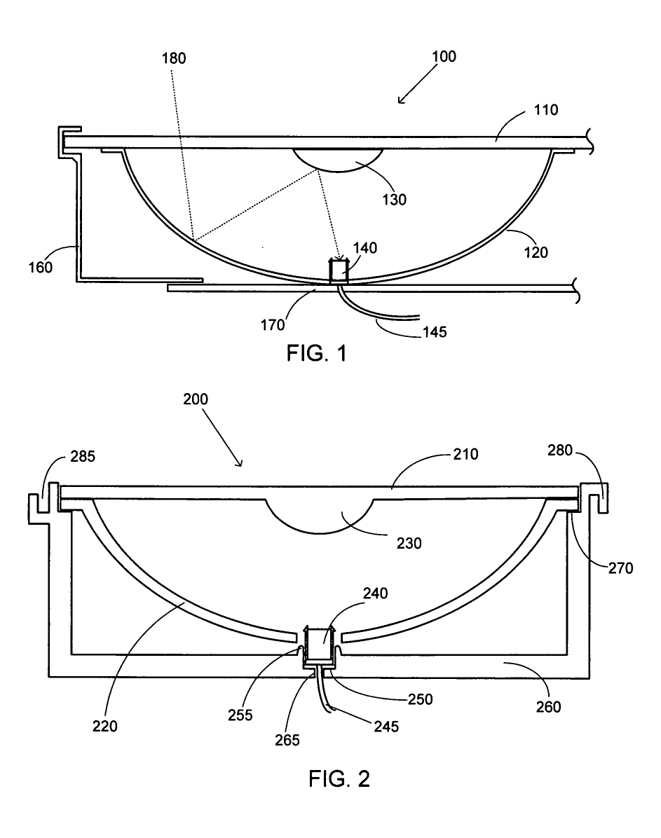

With reference to FIG. 1, an exemplary cross-sectional view of the solar power unit 100 in the afore-mentioned co-pending patent applications is shown. Note that for commercial application, the single power unit 100 would typically be replicated into an array of adjoining power units to form a complete solar panel. A front panel 110 covers the main optical elements of a primary mirror 120, a secondary mirror 130, and a solar receiver assembly 140. Protective front panel 110 is a substantially planar surface, such as a window or other transparent covering, which provides structural integrity for a power unit and protection for other components thereof. Sunlight 180 enters the solar unit 100 through front panel 110 and reflects off of primary mirror 120 to secondary mirror 130, where it is further reflected and focused onto receiver assembly 140. In one embodiment, receiver assembly 140 houses an optical rod and a photovoltaic cell where the intensified sunlight is converted into electrical energy. Energy is delivered out of the unit 100 through power output wire 145.

Continuing with FIG. 1, primary mirror 120 and secondary mirror 130 are substantially co-planar, at least a portion of both mirrors being in contact with front panel 110. In one exemplary embodiment, primary mirror 120 is generally circular and may have a diameter of approximately 280 mm and a depth of approximately 70 mm. Secondary mirror 130 is also generally circular, and is typically a first surface mirror using silver and a passivation layer formed on a substrate of soda-lime glass. In one embodiment, secondary mirror 130 may have a diameter of approximately 50 mm, and is adhered to front panel 110.

In this original configuration of the solar concentrator system as depicted in FIG. 1, a housing 160 and separate back panel 170 are used to properly align the mirrors 120 and 130 and front panel 110. Housing 160 is a frame designed to enclose the total number of power units in a given solar energy array, and back panel 170 is used to secure solar receivers 140 in the array and to serve as a heat dissipation element. Housing 160 and back panel 170 may be attached to the solar energy system by bolts, screws, or similar means (not shown) well-known in the art. Because back panel 170 and housing 160 are separate components, there is inherent tolerance error in their placements during assembly. This error is in turn compounded by primary mirror 120 and secondary mirror 130 each having tolerance errors in their attachments to back panel 170 and housing 160, respectively. Thus, proper alignment of the optical elements relies heavily on proper tooling, such as mounting templates, and on precise manual assembly. Alignment errors and tooling costs are further multiplied in an array of many solar power units. Moreover, specific tooling must be made for each different size of array, such as an array of 10 cells or 32 cells.

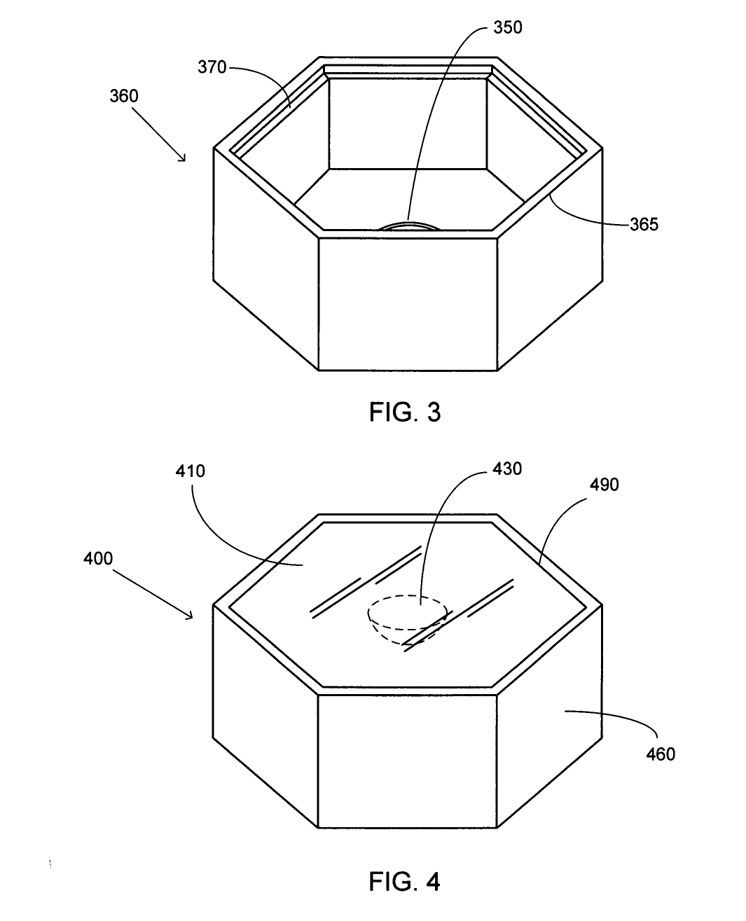

Turning now to FIG. 2, an improved design for aligning optical components is described. Outer structure 260 combines the previous back panel and housing of FIG. 1 into a single component which protects its contents from environmental conditions. Outer structure 260 can be fabricated from processes such as plastic injection-molding, sheet-metal stamping, metal casting, and the like. The materials for front panel 210 and outer structure 260 are preferably chosen to have similar coefficients of thermal expansion, also known as “CTE” or “α.” For instance, a front panel 210 constructed from glass with a CTE of 8.5 in/in/° F. would be compatible with carbon steel outer structure 260 having a CTE of 10.8 in/in/° F. Possible plastic materials for outer structure 260 include ABS, polycarbonate, or recycled plastic. In one embodiment, outer structure 260 may have a wall thickness ranging from 1-3 mm and may include stiffening ribs and bosses as necessary. FIG. 3 provides a perspective view of an exemplary outer structure 360, which is a self-contained water-tight and modular unit. Thus, individual units in an array can be replaced when necessary, and the size of an array can be easily varied by bundling the desired number of units together.

Returning to FIG. 2, the solar power unit 200 is assembled by placing elements into the outer structure 260, similar to dropping items into a bucket. Outer structure 260 contains integral features for aligning the various components as they are inserted. For example, alignment nubs 255 and recessed space 250 are used to set the placement of solar receiver 240. Note that the nubs 255 and recessed space 250 may be used exclusively of each other. An alignment groove 270, which is formed around the upper opening of the outer structure 260, guides primary mirror 220 and front panel 210 into proper position. Although not shown, alignment means for the front panel 210, primary mirror 220, and solar receiver 240 may additionally include features for constraining the parts from shifting vertically within the solar unit. For instance, indentations in the side walls of recessed space 250 or extension tabs at the upper surface of groove 270 could enable snap fits with mating features incorporated into the components being inserted. Parts could snap into place with plastic flexures, sheet metal clips, or wireform springs. As another example, the recessed space 250 and solar receiver 240 may be threaded. Threads would hold the solar receiver 240 securely in place in addition to aligning it within the solar unit. Alternatively, components may be secured into place using adhesive. Because the alignment features which have been described are integral to outer structure 260 and are thus fixed in position relative to each other, the need for costly tooling to assemble the solar power unit is reduced or eliminated.

Still referring to FIG. 2, power output wire 245 exits the enclosure through hole 265. Hole 265 is shown to be located in the bottom of outer structure 260 but could alternatively be located in the side walls of structure 260. The solar unit 200 is made water-tight by sealing hole 245 as well as groove 270 with a sealant such as silicone, silicone compounds incorporating butyl or urethane, or other polymers which can accommodate flexure between parts.

Another improvement shown in FIG. 2 is that secondary mirror 230 may be integrally formed with front panel 210 so that it is intrinsically positioned in the proper location on front panel 210. The combined mirror/panel component is formed from glass or optically transmissive plastic, such as polycarbonate, with secondary mirror portion 230 being coated with silver or other appropriate reflective substance. FIG. 2 further depicts an optional lip 280 which may be used to interlock solar units by mating with groove 285 of an adjacent unit. The lip 280 and corresponding groove 285 could extend along a length of the perimeter of outer structure 210, or be a shortened, discrete feature similar to a tab with mating slot.

As previously mentioned, FIG. 3 is a perspective view of an exemplary outer structure 360. In this embodiment, the perimeter 365 of structure 360 forms a hexagonal shape and includes alignment groove 370 around its upper opening. The hexagonal structures 360 combine in an array to form a honeycomb pattern, which is inherently resistant to structural stresses such as wind deformation loads. Alternatively, the perimeter of outer structure 360 may take the form a square or other polygonal shape. Recessed space 350 for locating the solar receiver is shown in the bottom surface of 360 as a circular cut-out. However, the space could take other shapes as necessary to accommodate the solar receiver assembly. For instance, it may be desired to have the solar receiver mounted on a heat sinking component prior to insertion into the outer structure 360. In that case, the recessed space 350 would be a larger cut-out in the shape of the heat sink component being used.

Now turning to FIG. 4, an assembled solar power unit 400 with secondary mirror 430 mounted on the underside of front panel 410 and enclosed within outer structure 460 is depicted. Front panel is sealed around edge 490 to make the enclosure water-tight and weather-proof. In this embodiment, no interlocking features are incorporated on the outer structure. The solar concentrator units may be joined into an array by such methods as bonding the walls of the units to each other or by placing a band clamp around the perimeter of the array. Alternatively, the units may be mounted onto a back panel or frame rather than to each other. In one embodiment, the units would be mounted in a manner that would allow them to be removed individually for repair. Note that the modularity of the solar power units allows for flexibility in forming various sizes of arrays.

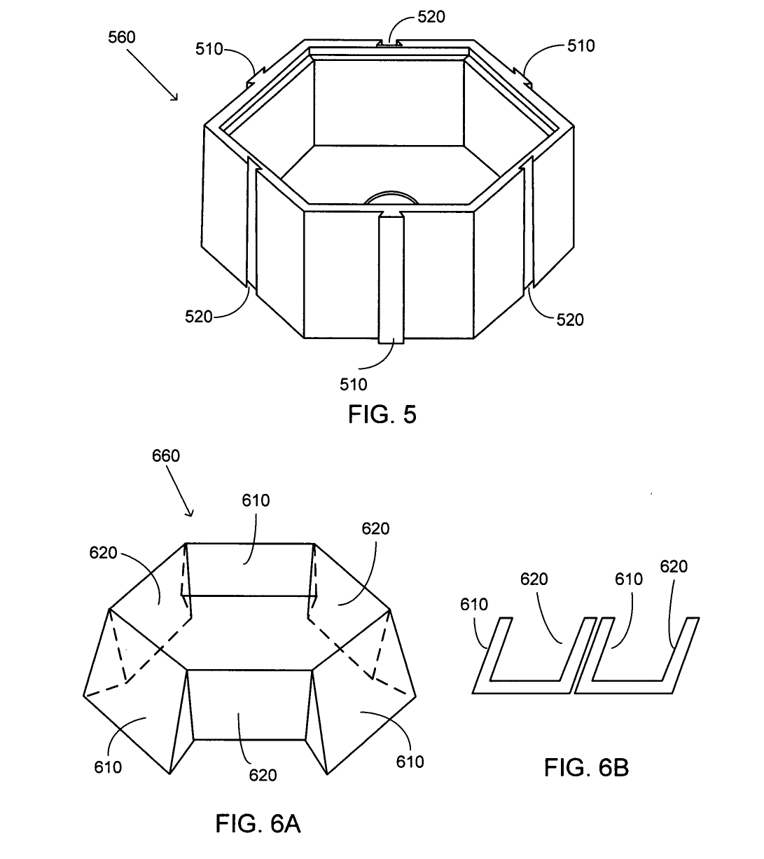

FIG. 5 illustrates another means for connecting solar units. Vertical projections 510 and mating grooves 520 are present on alternating walls of outer structure 560. Although the grooves and projections are shown as spanning the entire height of the unit, it is not necessary for this to be the case. For instance, projections 510 and grooves 520 could extend from the upper surface to halfway down, or from the bottom surface to halfway up. Moreover, the cross-section of projections 510 and grooves 520 could vary from the dovetail configuration as illustrated, such as being curved or rectangular in cross-section.

In FIG. 6A, yet another mode for interlocking units is shown in a simplified sketch of the outer structure. Instead of being vertical, the walls of outer structure 660 may be inclined. Outwardly slanting walls 610—those with a “positive draft”—would mate with inwardly slanting walls 620—those with a “negative draft.” A cross-sectional view of two adjacent outer structures with slanted walls can be seen in FIG. 6B. The slanted walls provide structural support for each other to form an overall rigid array.

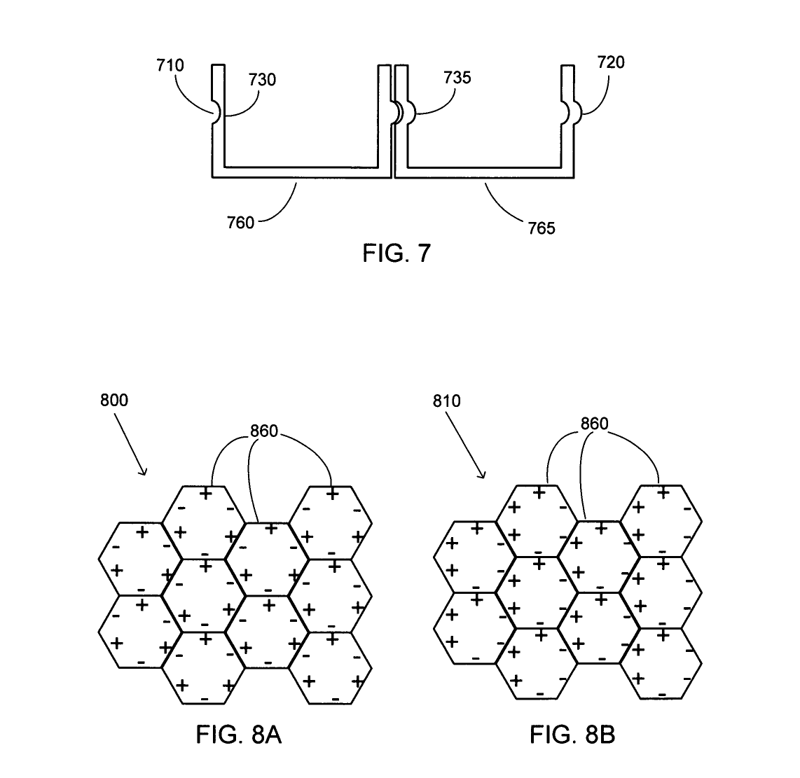

FIG. 7 is a cross-sectional schematic of two outer structures 760 and 765 which are connected in an alternative manner. Outer structures 760 and 765 are shown here without internal alignment features for clarity. In this configuration, bumps 720 formed on the exterior of outer structures 760 and 765 fit into indentations 710 formed on an opposite wall. As can be seen in FIG. 7, the interior of wall 730 may remain flush, as in outer structure 760 when formed by a process such as injection molding. However, in a process such as sheet-metal stamping, the interior of wall 735 may take the shape of the connecting feature as shown in outer structure 765.

Now considering an array of solar concentrator units, FIGS. 8A and 8B demonstrate patterns of interlocking units in arrays 800 and 810, respectively. In this embodiment, hexagonally shaped units 860 are shown, but other polygonal shapes such as squares may be used. Male and female features, such as the lip 280 and groove 285 of FIG. 2, the projection 510 and slot 520 of FIG. 5, and slanted walls 610 and 620 of FIG. 6, are designated as “+” and “−” respectively. In FIG. 8A, male and female features are on alternating walls. FIG. 8B illustrates another pattern where “+” are adjacent on one half of each unit 860, and “−” are on the adjacent walls that form the other half of the unit.

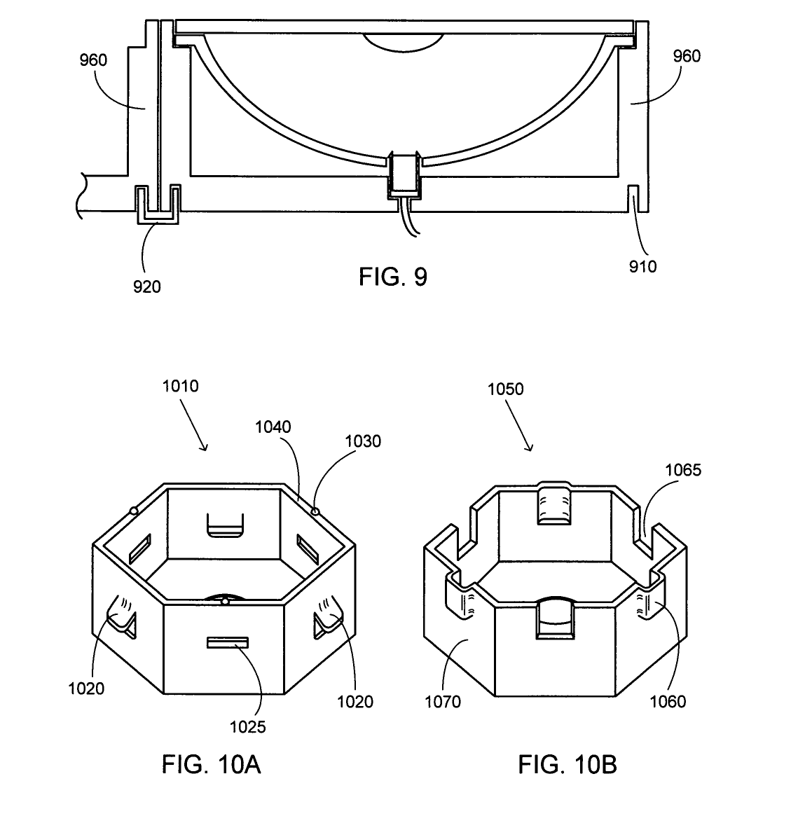

FIG. 9 depicts an additional method for joining solar concentrator units in an array. In this configuration, the outer structures 960 are secured together by inserting clip 920 into slots 910. Use of detachable clips 920 allows for easy removal of individual units for replacement or repair.

Two further embodiments for connecting solar concentrator units are shown in FIGS. 10A and 10B. In FIG. 10A, tabs 1020 are formed from the walls of outer structure 1010. Tabs 1020 are inserted into slots 1025 of an adjacent structure, and may be folded after insertion to more securely attach the structures. FIG. 10A also depicts nubs 1030 as an alternative alignment means. Instead of a groove around the upper opening of the outer structure as previously described, protruding nubs 1030 are seated on a flush upper opening surface 1040. Nubs 1030 may align the front panel by serving as an outer alignment edge, or may serve as registration points by fitting into indentations formed into the underside of the front panel.

In FIG. 10B, protrusions 1060 are formed from the walls of the outer structure 1050, and fit into openings 1065 of an adjoining unit. Protrusions 1060 and openings 1065 are shown at the upper surface of outer structure 1050, but may be located elsewhere within the wall 1070 of outer structure 1050, such as centered on wall 1070. For both configurations shown in FIGS. 10A and 10B, sealant may be applied around the slots 1025 or openings 1065 after the units are joined into an array to ensure protection against environmental elements.

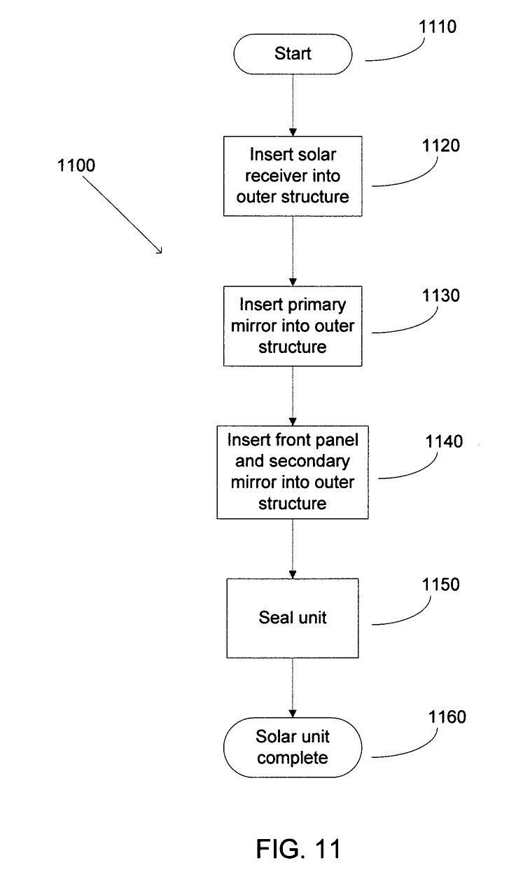

FIG. 11 is a simplified flowchart illustrating the basic steps in assembling a solar energy unit using the “bucket” outer structure design. In FIG. 11, flowchart 1100 is entered at step 1110. Step 1120 comprises inserting and securing the solar receiver assembly into the outer structure. Note that the sub-components of the solar receiver assembly—printed circuit board, solar cell, and optical rod—may be inserted separately, or maybe pre-built and inserted as an assembly. As part of step 1120, the power output wire is fed out of the outer structure. In the case where the solar receiver and corresponding alignment means do not have snap fit or other securing means, the solar receiver may be secured into its position by applying adhesive prior to insertion, attaching brackets, or by other means. Next, in step 1130, the primary mirror is placed into the enclosure. The front panel, with other items (e.g., secondary mirror), is then inserted into the outer structure in step 1140. Again, if the front panel and primary mirror are not secured to the outer structure by features integral to the outer structure, they may be secured into position by applying adhesive prior to insertion, by utilizing screws, or by other means. Lastly, in step 1150 the unit is sealed shut by applying sealant around edges of the front panel and in the hole through which the power output wire exits the outer structure.

Although embodiments of the invention have been discussed primarily with respect to specific embodiments thereof, other variations are possible. Lenses or other optical devices might be used in place of, or in addition to, the primary and secondary mirrors or other components presented herein. For example, a Fresnel type of lens could be used to focus light on the primary optical element, or to focus light at an intermediary phase after processing by a primary optical element.

It may be possible to use non-planar materials and surfaces with the techniques disclosed herein. Other embodiments can use optical or other components for focusing any type of electromagnetic energy such as infrared, ultraviolet, radio-frequency, etc. There may be other applications for the fabrication method and apparatus disclosed herein, such as in the fields of light emission or sourcing technology (e.g., fluorescent lighting using a trough design, incandescent, halogen, spotlight, etc.) where the light source is put in the position of the photovoltaic cell. In general, any type of suitable cell, such as a photovoltaic cell, concentrator cell or solar cell can be used. In other applications it may be possible to use other energy such as any source of photons, electrons or other dispersed energy that can be concentrated.

Steps may be performed by hardware or software, as desired. Note that steps can be added to, taken from or modified from the steps in this specification without deviating from the scope of the invention. In general, any flowcharts presented are only intended to indicate one possible sequence of basic operations to achieve a function, and many variations are possible.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention.

What is claimed is:

1. A solar concentrator unit, comprising:
an outer structure having an upper opening, an enclosed bottom surface, and supporting walls;
a primary mirror placed in said outer structure;
a front panel covering said upper opening of said outer structure; and
a solar receiver to convert solar energy into electricity, wherein said solar receiver is positioned to receive solar energy reflected from said primary mirror;
wherein said outer structure comprises integral means for aligning at least one optical component in said solar concentrator unit.

2. The solar concentrator unit of claim 1, wherein said optical component is chosen from the group consisting of said primary mirror, said front panel, and said solar receiver.

3. The solar concentrator unit of claim 1, further comprising a secondary mirror adjoining said front panel, wherein said secondary mirror is positioned to reflect said solar energy from said primary mirror to said solar receiver.

4. The solar concentrator unit of claim 3, wherein said secondary mirror is integrally formed with said front panel.

5. The solar concentrator unit of claim 1, wherein said integral means for aligning comprises a first integral means for aligning said primary mirror within said solar concentrator unit, a second integral means for aligning said front panel within said solar concentrator unit, and a third integral means for aligning said solar receiver within said solar concentrator unit.

6. The solar concentrator unit of claim 1, wherein said outer structure is formed by sheet metal stamping.

7. The solar concentrator unit of claim 1, wherein said outer structure is formed by plastic molding.

8. The solar concentrator unit of claim 1, wherein said supporting walls of said outer structure form a hexagonal shape.

9. The solar concentrator unit of claim 1, wherein said outer structure includes a connecting mechanism capable of connecting to a second outer structure, wherein said second outer structure is part of a second solar concentrator unit.

10. The solar concentrator unit of claim 9, wherein said connecting mechanism is at least one of a lip and groove located on said upper opening, a vertical projection and groove located on said supporting walls, an inclined wall, a bump and mating indentation on said supporting walls, a tab and slot in said supporting walls, a protrusion and opening in said supporting walls, and a slot in said bottom surface to receive a fastening clip.

11. A solar concentrator unit, comprising:
an outer structure having an upper opening, an enclosed bottom surface, supporting walls, and a connecting mechanism;
a primary mirror placed in said outer structure;
a front panel covering said upper opening of said outer structure; and
a solar receiver to convert solar energy into electricity, wherein said solar receiver is positioned to receive solar energy reflected from said primary mirror;
wherein said connecting mechanism is capable of connecting to a second outer structure, and wherein said second outer structure is part of a second solar concentrator unit.

12. The solar concentrator unit of claim 11, wherein said solar concentrator unit is combined with said second solar concentrator unit and other solar concentrator units to form a solar concentrator array.

13. The solar concentrator unit of claim 12, wherein said solar concentrator unit may be individually removed from said solar concentrator array.

14. The solar concentrator unit of claim 11, wherein said outer structure comprises integral means for aligning at least one optical component in said solar concentrator unit, wherein said optical component is chosen from the group consisting of said primary mirror, said front panel, and said solar receiver.

15. The solar concentrator unit of claim 11, further comprising a secondary mirror adjoining said front panel, wherein said secondary mirror is positioned to reflect said solar energy from said primary mirror to said solar receiver.

16. The solar concentrator unit of claim 11, wherein said outer structure is formed by sheet metal stamping.

17. The solar concentrator unit of claim 11, wherein said outer structure is formed by plastic molding.

18. The solar concentrator unit of claim 11, wherein said connecting mechanism is at least one of a lip and groove located on said upper opening, a vertical projection and slot located on said supporting walls, an inclined angle of said supporting walls, a bump and mating indentation on said supporting walls, a tab and slot in said supporting walls, a protrusion and opening in said supporting walls, and a slot in said bottom surface to receive a fastening clip.

19. A method of assembling a solar concentrator unit, comprising:
positioning a solar receiver in an outer structure, said outer structure comprising an upper opening and an enclosed bottom surface and supporting walls, said outer structure having integral means for aligning said solar receiver in said outer structure, said solar receiver being capable of converting solar energy into electricity;
placing a primary mirror in said outer structure, said primary mirror positioned to reflect said solar energy; and
covering said upper opening of said outer structure with a front panel.

20. The method of assembling a solar concentrator unit of claim 19, wherein said outer structure further comprises:
a second integral means for aligning, wherein said second integral means for aligning aligns said primary mirror in said outer structure; and
a third integral means for aligning, wherein said third integral means for aligning aligns said front panel on said upper surface of said outer structure.

21. The method of assembling a solar concentrator unit of claim 19, wherein said front panel has an adjoining secondary mirror, said secondary mirror positioned to reflect solar energy from said primary mirror to said solar receiver.

22. The method of assembling a solar concentrator unit of claim 19, wherein said outer structure comprises a connecting mechanism capable of connecting to a second outer structure, and wherein said second outer structure is part of a second solar concentrator unit.
